(19) United States
(12) Patent Application Publication
(10) Pub. No.: US 2024/0186957 A1
(43) Pub. Date: Jun. 6, 2024

(54) SYSTEM AND METHOD FOR MANAGING THE OPERATION OF A TRAVELLING WAVE TUBE AMPLIFIER

(71) Applicant: THALES, MEUDON (FR)

(72) Inventors: Eric PEQUET, Mont-sur-Marchienne (BE); Xavier LISMONDE, Mont-sur-Marchienne (BE); Philippe FAYT, Mont-sur-Marchienne (BE)

(21) Appl. No.: 18/523,766

(22) Filed: Nov. 29, 2023

(30) Foreign Application Priority Data
Dec. 2, 2022 (EP) 22306781.0

(51) Int. Cl. H03F 1/06; H03F 3/189

(52) U.S. Cl. CPC H03F 1/06; H03F 3/189; H03F 2200/451

(57) ABSTRACT

A satellite system includes a radio frequency signal amplifier device comprising a control and supply module and a plurality of travelling wave tubes. The module is configured to apply to at least one of the tubes an anode voltage operating value, generating a cathode current in response. The module is moreover configured to measure at least one sum of the cathode currents that is associated with the plurality of tubes, the at least one measurement of the sum of the cathode currents being implemented on the basis of a single measuring circuit, and to determine at least one corrected anode voltage operating value, associated with the at least one of the tubes, on the basis of the at least one measurement of the sum of the cathode currents.

### CROSS-REFERENCE TO RELATED APPLICATION

This application claims priority to foreign European patent application No. EP 22306781.0, filed on Dec. 2, 2022, the disclosure of which is incorporated by reference in its entirety.

### FIELD OF THE INVENTION

The present invention relates generally to the field of travelling wave tube amplifiers, and in particular to a system and method for managing the operation of a travelling wave tube amplifier integrated in a satellite.

### BACKGROUND

A travelling wave tube amplifier is used to transmit high-power radio frequency (RF) signals. A travelling wave tube amplifier comprises one or more travelling wave tubes controlled (or powered) by a high-voltage power supply.

As shown diagrammatically in FIG. 1, a travelling wave tube comprises an input for a radio frequency signal RF IN and an output for a radio frequency signal RF OUT, a delay line 1021, and electrodes comprising a cathode 1022 and an anode 1023, also called a “anode zero”.

The cathode 1022 is brought to an operating temperature (typically 1000° C.) by applying a voltage to the filament. When the cathode 1022 has reached the operating temperature, an electrical potential difference between the anode 1023 and the cathode 1022 is applied. In particular, this electrical potential difference Va0 can also be called an “anode voltage” or an “anode zero voltage”. When the anode voltage Va0 is applied, the cathode 1022 emits a very dense electron beam 1024 called the “cathode current” and denoted Ik.

The delay line 1021 (also called the “helix”) is a spiral to which the input microwave signal (or wave) RF IN is applied and through which the electron beam 1024 passes. When the electron beam 1024 moves through the helix 1021, an interaction is created between the helix and the RF signal, and part of the kinetic energy of the electrons of the beam 1024 is transferred to the microwave. The amplitude of the microwave at the radio frequency output RF OUT of the helix 1021 is then amplified.

In particular, the value of the cathode current Ik and the speed of the electron beam 1024 of a travelling wave tube make it possible to predefine the performance of this tube. Some performance, called “RF performance”, may be for example the power at saturation, corresponding to the maximum power, and the frequency band of the radio frequency output signal RF OUT, or the gain of the tube, corresponding to the ratio between the output power RF OUT and the power of the radio frequency input signal RF IN. Other performance parameters of a tube may be its consumption or the energy dissipation, which take into account emissivity dispersion of the cathodes. A travelling wave tube may be associated with one or more specific and/or optimum operating points PF that take into account the performance of this tube. Thus, each operating point PF of a tube is associated with a specific cathode current value Ik.

Moreover, the emissivity of a cathode 1022 varies mainly with the operating temperature of the cathode 1022. The operating temperature of the cathode 1022 depends on the heating power of the filament. The emissivity of a cathode 1022 may also deteriorate as a function of the operating time of the cathode 1022. Variations in the emissivity of a cathode 1022 generate an average drift in the performance of this tube 1020-n over time. Thus, in order to maintain the flow of electrons of the beam 1024 and consequently the performance of the tube, it is thus necessary to modify the anode voltage Va0 (or anode voltage operating value, also called “anode zero voltage operating value”) in an appropriate manner, in particular for a given voltage on the filament.

Traditionally, to optimize the radio frequency performance of a tube, the amplifier adjusts the flow of electrons from the cathode of this tube on the basis of the direct measurement of the cathode current Ik of the tube.

In view of the high-voltage value to which the cathode is brought, a circuit for directly measuring the cathode current Ik is complex to implement, in particular in view of the high-voltage insulation to be observed (for example 6 to 9 kV).

In existing solutions, it is known practice to use multiple travelling wave tubes connected to a single high-voltage power supply. Moreover, in order to manage the variations in operating points PF, that is to say the variations in electron flows from the cathode of travelling wave tubes, the high-voltage power supply individually adjusts the operating point PF of the tube for each tube. In particular, controllers specific to each tube measure the cathode current Ik for each tube and then transfer this value to a potential of the controller (for example the cathode voltage, the anode voltage or ground) and a control circuit so as to generate a correction value, via a high-voltage value of the anode of the tube. The mass, the volume and the cost of each of the circuits for directly measuring the cathode current Ik are thus multiplied by the number of tubes supplied with power by the same power supply. This situation is particularly critical in certain fields of application, and in particular for travelling wave tube amplifiers used in space.

Other examples of the management of travelling wave tube amplifier systems are proposed in the documents U.S. Pat. No. 6,044,001 A and US 2006/234626 A1. In particular, the solution proposed in the document U.S. Pat. No. 6,044,001 A operates in open-loop mode over a series of predefined operating points, and the solution proposed in the document US 2006/234626 A1 operates in open-loop mode over the envelope of the RF signal applied to the tube.

Thus, there is a need for a travelling wave tube amplifier device capable of improving the management of operation and the adjustment of the high-voltage power supply vis-à-vis travelling wave tubes.

### SUMMARY OF THE INVENTION

The present invention improves the situation by proposing a satellite system comprising a radio frequency signal amplifier device, the amplifier device comprising a control and supply module and a plurality N of travelling wave tubes. The control and supply module is configured to apply, for at least one of the tubes, an anode voltage operating value Va0ₙ, the tube generating a cathode current Ik in response to application of the anode voltage operating value Va0ₙ. The control and supply module is configured to measure at least one sum of the cathode currents MΣIk that is associated with the plurality N of travelling wave tubes, the at least one measurement of the sum of the cathode currents being implemented on the basis of a single measuring circuit. The control and supply module is moreover configured to determine at least one corrected anode voltage operating value associated with at least one of the tubes on the basis of the at least one measurement of the sum of the cathode currents.

Advantageously, each tube may be associated with a given operating point PFₙ associated with a cathode current setpoint value CIkₙ and with an anode voltage setpoint value CVa0ₙ. The control and supply module may be configured to apply the anode voltage setpoint value CVa0ₙ to each tube. The control and supply module may be configured to activate a correction mode and to perform, during the correction mode:

a single measurement of the sum of the cathode currents MΣIk that is associated with the plurality N of travelling wave tubes at the operating points PFₙ,

for each tube, a determination of a corrected anode voltage value DVa0ₙ on the basis of the single measured sum of the cathode currents MΣIk, the cathode current setpoint value CIkₙ and the anode voltage setpoint value CVa0ₙ.

The control and supply module may moreover be configured to apply, during the correction mode, the associated corrected anode voltage value DVa0ₙ to each tube.

In a number of embodiments, the determination, for each tube, of the corrected anode voltage value DVa0ₙ may be performed on the basis of an estimated perveance value DGₙ and the cathode current setpoint value CIkₙ, the corrected anode voltage value DVa0ₙ being defined by:

$$DVa {0}_{n} = {( \frac{{CIK}_{n}}{{DG}_{n}} )}^{+ 2 / 3} .$$

In other embodiments, the determination, for each tube, of the corrected anode voltage value DVa0ₙ of the travelling wave tube may be performed on the basis of a derivative formula for the cathode current with respect to the anode voltage of the tube at the operating point PFₙ.

The control and supply module may be configured to moreover perform, during the correction mode, a determination of a drift ratio QΣIK on the basis of the single measured sum of the cathode currents MΣIk and a sum of the cathode current setpoint values CIkₙ of the plurality N of tubes.

In some embodiments, application, during the correction mode, of the corrected anode voltage value DVa0ₙ to the tube may be performed in response to a detection of a performance drift of at least one tube from the plurality N of travelling wave tubes.

The control and supply module may comprise a data set comprising the stored operating points PFₙ. The performance drift may be determined on the basis of a comparison of at least one estimated perveance value DGₙ with a perveance setpoint value CGₙ included in the data set.

The control and supply module may comprise a data set comprising the stored operating points PFₙ. The performance drift may be determined on the basis of a comparison of the drift ratio QΣIK with a drift threshold included in the data set.

Advantageously, the performance drift may be determined on the basis of a comparison, for at least one of the tubes, of the corrected anode voltage value DVa0ₙ with the associated anode voltage setpoint value CVa0ₙ.

The control and supply module may comprise an internal clock and the correction mode may be activated in response to a detection of a predefined time stamp.

The control and supply module may comprise an internal clock and a data set comprising the stored operating points PFₙ. The control and supply module may be configured to store in a calibration table and to associate a time stamp with the corrected anode voltage value DVa0ₙ and/or the estimated perveance value DGₙ, and to store, each time the correction mode is activated, the corrected anode voltage value DVa0ₙ and/or the estimated perveance value DGₙ in the data set. The control and supply module may moreover be configured to calculate, for at least one tube from the plurality N of travelling wave tubes, a trend curve on the basis of the data set, and to estimate at least one predicted anode voltage value PVa0ₙ and/or a predicted perveance value PGₙ, associated with a predefined subsequent time stamp value.

Advantageously, each tube may be associated with a given operating point PFₙ associated with an anode voltage setpoint value CVa0ₙ and a cathode current setpoint value CIkₙ. The control and supply module may be configured to activate a calibration mode and to perform, during the calibration mode:

for a single tube from the plurality N of travelling wave tubes, an application of a first anode voltage value to the tube,

a first measurement of the sum of the calibration cathode currents MΣIk¹ that is associated with the plurality N of travelling wave tubes,

for the single tube, an application of a given second anode voltage value BVa0ₙ to the tube,

a second measurement of the sum of the calibration cathode currents MΣIk² that is associated with the plurality N of travelling wave tubes,

a comparison of the first and second measurements of the sum of the calibration cathode currents MΣIk¹ and MΣIk²;

The control and supply module may moreover be configured to perform an update of the anode voltage setpoint value CVa0ₙ on the basis of the given second anode voltage value BVa0ₙ and according to the comparison.

In a number of embodiments, the first anode voltage value may be an anode voltage reference value RVa0ₙ associated with a cathode current reference value RIkₙ. For the single tube, the comparison may moreover be performed on the basis of a calibration accuracy setpoint ϵ, the cathode current setpoint value CIkₙ and the cathode current reference value RIkₙ, such that |MΣIk²−MΣIk¹−CIkₙ+RIkₙ|<ϵ.

The calibration mode may be activated in response to detection of a performance drift.

The invention also provides a method for controlling and supplying power to a plurality of N travelling wave tubes. The method may be implemented in a satellite system comprising the travelling wave tubes. The method may comprise an initial step of applying a anode voltage operating value Va0ₙ to at least one of the tubes, the tube generating a cathode current Ik in response to application of the anode voltage operating value Va0ₙ. The method may comprise the steps of:

measuring at least one sum of the cathode currents that is associated with the plurality N of travelling wave tubes, the at least one measurement of the sum of the cathode currents being implemented on the basis of a single measuring circuit,

determining at least one corrected anode voltage operating value associated with at least one of the tubes on the basis of the at least one measurement of the sum of the cathode currents.

The system and method for managing the operation of a travelling wave tube amplifier according to the embodiments of the invention make it possible to simplify the implementation of the high-voltage power supply vis-à-vis travelling wave tubes.

They provide an efficient solution while limiting the manufacturing costs of the high-power radio frequency signal amplifier and reducing the weight, volume and associated costs.

### DESCRIPTION OF THE DRAWINGS

Other features, details and advantages of the invention will become apparent on reading the description provided with reference to the appended drawings, which are given by way of example.

FIG. 1 is a diagram showing a travelling wave tube according to the prior art.

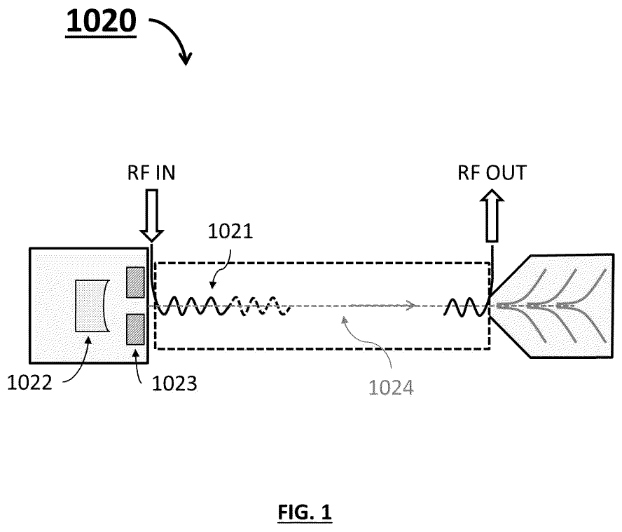

FIG. 2 is a diagram showing a radio frequency signal amplifier according to embodiments of the invention.

FIG. 3 is a graph showing the evolution of the anode voltage to be applied as a function of a drift ratio, according to embodiments of the invention.

FIG. 4 is a flowchart showing steps of the method for managing the operation of travelling wave tubes, according to embodiments of the invention.

FIG. 5 is a flowchart showing steps of the method for managing the operation of travelling wave tubes, according to embodiments of the invention.

Identical references are used in the figures to denote identical or similar elements. For the sake of clarity, the elements that are shown are not to scale.

### DETAILED DESCRIPTION

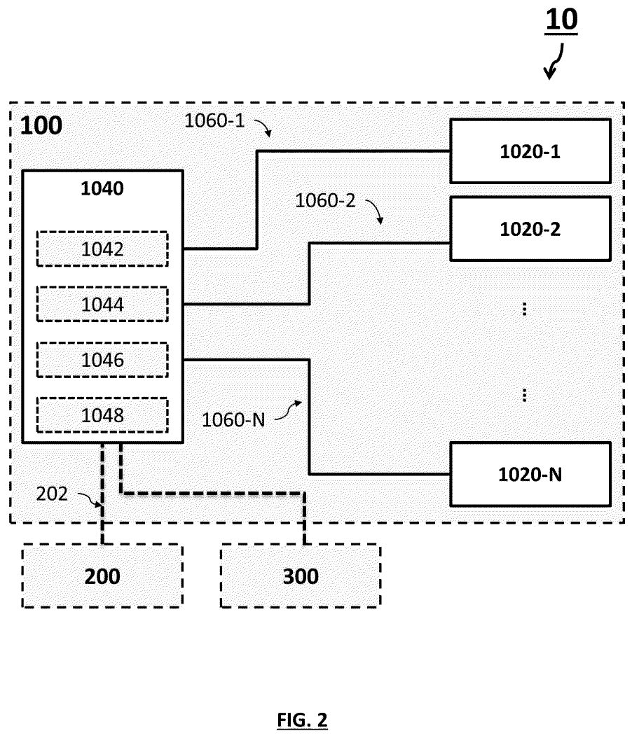

FIG. 2 diagrammatically shows a device 100 comprising a plurality of N travelling wave tubes 1020-n and a control and supply module 1040, according to embodiments of the invention.

The index “n” is used to designate the nth tube among the various travelling wave tubes, and is thus between 1 and N. The number N is greater than 1. For example and without limitation, the number N may be equal to 4 or to 8.

The device 100 is a travelling wave tube amplifier, also called a TWTA. In an example of application of the invention to the satellite field, the device 100 may be aboard a satellite system 10 and used to generate and transmit high-power radio frequency signals towards the ground, for example a telecommunication satellite.

The radio frequency signal amplifier device 100 may deliver a few hundred watts, for example, and operate at high frequency (or microwave frequency). In particular, the amplifier device 100 may reach frequencies up to the W band of 100 GHz, for example.

A travelling wave tube 1020-n, also called a TWT, is an elongated vacuum tube used in the device 100 to produce low-, medium- or high-power microwave amplifiers.

In a number of embodiments, the device 100 may be a TWTA having multiple TWTs. In these embodiments, one or more travelling wave tubes 1020-n may comprise a housing incorporating M travelling wave tubes (not shown in the figures).

The device 100 moreover comprises one or more high-voltage cables 1060-n connecting one or more tubes 1020-n to the control and supply module 1040. A high-voltage cable can be used to supply high voltage to at least one travelling wave tube. The control and supply module 1040 comprises a high-voltage power supply or an electronic power conditioner, called an EPC, configured to transform a low-voltage supply voltage into multiple high voltages used to supply power to the N travelling wave tubes 1020-n. The control and supply module 1040 may comprise one or more DC-DC power converters supplied with energy by a power bus (or primary bus) 202 connected to an electrical supply source 200 of the satellite 10.

Each tube 1020-n is associated with one or more specific and/or optimum operating points denoted PFₙⱼ. The index “j” is used to designate a j-th operating point of a travelling wave tube 1020-n among the various operating points of the tube 1020-n, and is thus between 1 and J, J being greater than or equal to 1. Each specific and/or optimum operating point PFₙⱼ of a travelling wave tube 1020-n is associated with a cathode current setpoint value (denoted CIkₙ), and with an anode voltage setpoint value (also called “anode zero voltage setpoint value” and denoted CVa0ₙ). The remainder of the description will be provided with reference to a value of J equal to 1, an operating point of a travelling wave tube 1020-n then being denoted PFₙ.

The control and supply module 1040 is configured to apply an anode current setpoint value CVa0ₙ, to each tube 1020-n.

For a travelling wave tube 1020-n, in response to application of the anode voltage setpoint value CVa0ₙ, the cathode 1022 generates an electron beam 1024 characterized by a specific cathode current value, denoted Ikₙ.

In a number of embodiments, the operating points PFₙ (or PFₙⱼ) and the associated specific cathode current values and the associated anode voltage setpoint values may be stored in a data set, for example in a storage unit 1042 internal to the control and supply module 1040 and/or in a unit 300 external to the amplifier device 100. The external unit 300 may be, for example, programming equipment or the on-board computer, denoted OBC, of the satellite 10. The remainder of the description will be provided with reference to a data set shown in the form of a calibration table, by way of non-limiting example. The external unit 300 may also receive instructions from a ground centre.

As illustrated in FIG. 2, the control and supply module 1040 comprises a measuring unit 1044 configured to measure the value of the sum of the specific cathode current values Ikₙ associated with all N travelling wave tubes 1020-n of the radio frequency signal amplifier device 100. This value is hereinafter also called the “sum of the cathode currents” and denoted MΣIk.

It should be noted that, for one or more tubes 1020-n, the specific value Ikₙ of the cathode current, generated in response to application of the anode voltage setpoint value CVa0ₙ, may be different from the cathode current setpoint value, denoted CIkₙ, associated with this anode voltage setpoint value CVa0ₙ. A difference between the specific value Ikₙ of the generated cathode current and the cathode current setpoint value CIkₙ results from a variation in emissivity of the cathode 1022.

Thus, to maintain the performance of each of the travelling wave tubes 1020-n of the satellite 10, the control and supply module 1040 may be configured to activate a correction mode and to perform, during the correction mode:

a measurement of the sum of the cathode currents MΣIk, and

for each tube 1020-n, a determination of a corrected anode voltage value (also called “corrected anode zero voltage value”), denoted DVa0ₙ.

The control and supply module 1040 is moreover configured to apply, during the correction mode and to each tube 1020-n, the corrected anode voltage value DVa0ₙ.

The corrected anode voltage value DVa0ₙ may be estimated, for example via a determination unit 1046 internal to the control and supply module 1040, on the basis of the measured sum MΣIk of the cathode currents, the cathode current setpoint value CIkₙ and the anode voltage setpoint value CVa0ₙ.

In a first variant of the invention, the corrected anode voltage value DVa0ₙ may be determined using a formula for defining the perveance Gₙ of a travelling wave tube 1020-n according to the cathode current and the anode voltage. The formula for the perveance Gₙ may be defined using the following equation (01):

$${G}_{n} = \frac{{Ik}_{n}}{{( Va {0}_{n} )}^{3 / 2}} \qquad ( 01 )$$

It should be noted that the perveance Gₙ of a travelling wave tube 1020-n is specific to this tube 1020-n and is an image of the emissivity of the cathode. Thus, the perveance Gₙ of the travelling wave tube 1020-n varies with the life of the tube 1020-n and may be associated with the specific and/or optimum operating points of the tube 1020-n.

In a number of embodiments, the determination unit 1046 may be configured to estimate, for each tube 1020-n, the corrected anode voltage value DVa0ₙ on the basis of a perveance value, denoted DGₙ, estimated according to the cathode current setpoint value CIkₙ of the tube 1020-n, as defined by the following equation (02):

$$DVa {0}_{n} = {( \frac{{CIK}_{n}}{{DG}_{n}} )}^{+ 2 / 3} \qquad ( 02 )$$

In addition, the estimated perveance value DGₙ of a tube 1020-n may be estimated on the basis of an estimated cathode current value, denoted DIKₙ, and the anode voltage setpoint value CVa0ₙ, as defined by the following equation (03):

$${DG}_{n} = \frac{{DIK}_{n}}{{( CVa {0}_{n} )}^{3 / 2}} \qquad ( 03 )$$

The estimated cathode current value DIKₙ is in particular estimated on the basis of the measured sum MΣIK of the cathode currents.

In a number of embodiments, the estimated cathode current value DIKₙ of the tube 1020-n may be defined on the basis of the cathode current setpoint value CIkₙ and a drift ratio, denoted QΣIK, as defined by the following equation (04):

DIKₙ=CIKₙ×QΣIK (04)

In equation (04), the drift ratio QΣIK may be defined as the ratio of the measured sum MΣIK of the cathode currents to a sum Σₙ CIKₙ of the cathode current setpoint values CIkₙ on all tubes 1020-n. Thus, the drift ratio QΣIK may be expressed using the following equation (05):

$$Q Σ IK = \frac{M Σ IK}{{Σ}_{n} {CIK}_{n}} \qquad ( 05 )$$

The expression of the corrected anode voltage value DVa0ₙ to be applied for each tube 1020-n may thus be simplified by combining the previous equations (02), (03), (04) and (05). In particular, the expression of the corrected anode voltage value DVa0ₙ may be simplified using the following equations (06) or (07):

$$\begin{matrix}DVa {0}_{n} = CVa {0}_{n} \times {( \frac{1}{Q Σ IK} )}^{+ 2 / 3} & ( 06 ) \\ DVa {0}_{n} = CVa {0}_{n} \times {( \frac{{Σ}_{n} {CIK}_{n}}{M Σ IK} )}^{+ 2 / 3} & ( 07 )\end{matrix}$$

In a second variant of the invention, the corrected anode voltage value DVa0ₙ may be obtained by using a derivative formula for the cathode current with respect to the anode voltage of the tube 1020-n at the operating point PFₙ. In particular, the corrected anode voltage value DVa0ₙ may be obtained on the basis of the following equation (08):

$$\begin{matrix}DVa {0}_{n} = CVa {0}_{n} \times ( 1 - \frac{2}{3} \times ( Q Σ IK - 1 ) ) & ( 08 ) \\ DVa {0}_{n} = CVa {0}_{n} \times ( 1 + \frac{2}{3} \times ( 1 - \frac{M Σ IK}{{Σ}_{n} {CIK}_{n}} ) ) & ( 09 )\end{matrix}$$

According to equations (07) and (09), the corrected anode voltage value DVa0ₙ is estimated on the basis of the measured sum MΣIk of the cathode currents, the cathode current setpoint value CIkₙ and the anode voltage setpoint value CVa0ₙ.

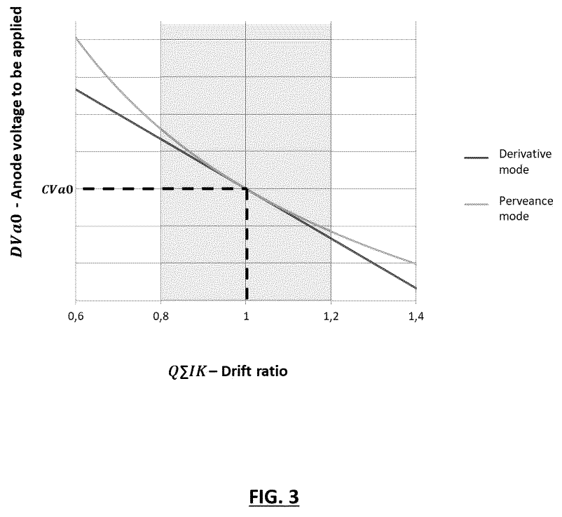

FIG. 3 is a graph showing the evolution of the corrected anode voltage value DVa0ₙ to be applied as a function of the drift ratio QΣIK, obtained on the basis of equations (06) and (08), according to the first and second variants of the invention. As illustrated in FIG. 3, the two variants of the invention are equivalent for a drift ratio QΣIK very close to 1, and up to 0.6% for an error of ±10% between the measured sum MΣIK of the cathode currents and the sum Σₙ CIKₙ of the cathode current setpoint values on all tubes 1020-n.

Advantageously, the determination unit 1046 may be configured to estimate, for each tube 1020-n, the estimated perveance value DGₙ the estimated cathode current value DIKₙ and/or the drift ratio QΣIK.

Moreover, the storage unit 1042 may be configured to store the corrected anode voltage value DVa0ₙ, and also the estimated perveance value DGₙ and/or the estimated cathode current value DIKₙ, associated with the tube 1020-n in the calibration table. The storage unit 1042 may also be configured to store the drift ratio QΣIK.

Advantageously, the control and supply module 1040 may comprise an internal clock (not shown in the figures), and the storage unit 1042 may be configured to store and associate with each of the stored values (estimated perveance value DGₙ, estimated cathode current value DIKₙ, and/or drift ratio QΣIK) a time stamp value defined by the internal clock. This time stamp value may be defined when measuring the sum of the cathode currents MΣIk in the correction mode.

In some embodiments, application of the corrected anode voltage values DVa0ₙ may be performed in response to detection of a performance drift. For example and without limitation, a performance drift may be determined on the basis of the comparison of one or more estimated cathode current values DIKₙ with a predefined cathode current value threshold. A performance drift may also be determined on the basis of the comparison of the corrected anode voltage values DVa0ₙ with the anode voltage setpoint values CVa0ₙ, the comparison of the estimated perveance values DGₙ with perveance setpoint values, denoted CGₙ (defined using equation (01) on the basis of the anode voltage setpoint values CIkₙ and the cathode current setpoint values CIkₙ) and/or the comparison of the drift ratio QΣIK with a predefined drift threshold.

Each tube 1020-n may also be associated with a reference operating point, denoted PFₙ₀. Each reference operating point PFₙ₀ of a travelling wave tube 1020-n is associated with a cathode current reference value, denoted RIkₙ, and with an anode voltage reference value (also called “anode zero voltage reference value”), denoted RVa0ₙ.

Advantageously, the control and supply module 1040 may be configured to activate a calibration mode and to perform, during the calibration mode:

for a single tube 1020-n to be calibrated, application of the anode voltage reference value RVa0n to the tube 1020-n,

a first measurement of the sum of the calibration cathode currents MΣIk¹,

for this single tube 1020-n to be calibrated, application of a given anode voltage value (also called “given anode zero voltage value”), denoted BVa0ₙ,

a second measurement of the sum of the calibration cathode currents MΣIk²,

a comparison of the first and second measurements of the sum of the calibration cathode currents MΣIk¹ and MΣIk², and

an update of the anode voltage setpoint value CVa0ₙ in the calibration table on the basis of the given anode voltage value BVa0ₙ and according to the comparison of the first and second sum measurements.

In a number of embodiments, the comparison performed during the calibration mode may moreover be defined on the basis of the cathode current setpoint value CIkₙ, the cathode current reference value RIkₙ, and a predefined calibration accuracy setpoint value, denoted ϵ. For example, the comparison performed during the calibration mode may be defined using the following equation (10):

|MΣIk²−MΣIk¹−CIkₙ+RIkₙ|<ϵ (10)

Thus, if equation (10) is verified, the anode voltage setpoint value CVa0ₙ in the calibration table may be replaced by the given anode voltage value BVa0ₙ applied to the tube 1020-n. If identity (10) is not verified, another given anode voltage value BVa0ₙ is chosen and then applied to the tube 1020-n and the calibration mode continues, taking a new second measurement of the sum of the calibration cathode currents MΣIk², and a new comparison of the first measurement of the sum of the calibration cathode currents MΣIk¹ with the new second measurement of the sum of the calibration cathode currents MΣIk².

The given anode voltage value BVa0ₙ may be chosen (that is to say sought) using successive approximation methods, for example.

According to some embodiments, the control and supply module 1040 may be configured to, before the calibration mode, cut off the supply of voltage to N−1 tubes and to apply the calibration mode of a single tube 1020-n that is then supplied with power so as to generate the electron beam 1024 of the tube 1020-n. In this case, the control and supply module 1040 may be configured to perform, during the calibration mode:

for this single tube 1020-n, application of a given anode voltage value BVa0ₙ,

a single measurement of the sum of the calibration cathode currents MΣIk⁰,

a comparison of the measured sum MΣIk⁰ of the calibration cathode currents with the cathode current setpoint value CIkₙ, using the following identity (11):

MΣIk⁰=CIkₙ (11),

and

an update of the anode voltage setpoint value CVa0ₙ in the calibration table on the basis of the given anode voltage value BVa0ₙ and according to the comparison.

Thus, if equation (11) is verified, the anode voltage setpoint value CVa0ₙ in the calibration table may be replaced by the given anode voltage value BVa0ₙ applied to the tube 1020-n. If identity (11) is not verified, another given anode voltage value BVa0ₙ is chosen and then applied to the tube 1020-n and the calibration mode continues, taking a new single measurement of the sum of the calibration cathode currents MΣIk⁰ and a new comparison of the cathode current setpoint value CIkₙ with the new single measurement of the sum of the calibration cathode currents MΣIk⁰.

The control and supply module 1040 may be configured to repeat application of the calibration mode to one or more other operating points PFₙⱼ of the same tube 1020-n, and/or to another tube 1020-n, to multiple tubes 1020-n, or to all the tubes 1020-n of the system 10. Repeating application of the calibration mode allows a complete or partial update of the calibration table. The control and supply module 1040 may also be configured to repeat application of the calibration mode by cutting off the supply of power to the previously controlled single tube 1020-n to be calibrated and by supplying power to another single tube 1020-n to be calibrated.

In a number of embodiments, the correction mode and/or the calibration mode may be triggered following the supply of power to one or more tubes 1020-n, in response to a change of operating point of a tube and/or in response to detection of a performance drift. In other embodiments, the correction mode and/or the calibration mode may also be triggered in response to a command from the module 1040 or from the external unit 300 of the amplifier device 100. This control for triggering the correction mode and/or the calibration mode may be programmed and/or induced by a ground centre.

Advantageously, in the embodiments where the control and supply module 1040 comprises an internal clock, the correction mode and/or the calibration mode may be triggered in response to detection of a predefined time stamp (for example via a programmed trigger command), for example periodically. For example and without limitation, the correction mode may be triggered every second whereas the calibration mode may be triggered every 3 to 6 months, for a certain number of years from the launch of the satellite 10, and then annually.

Thus, the control and supply module 1040 may comprise a learning unit 1048 configured to calculate, for one or more tubes 1020-n, a trend curve, on the basis of the values stored in the calibration table and the associated time stamp values. The learning unit 1048 may thus be configured to predict (i.e. estimate), on the basis of the trend curve, using an equation adapted for the trend curve, for example, one or more predicted anode voltage values (also called “predicted anode zero voltage values”), denoted PVa0ₙ and/or one or more predicted perveance values, denoted PGₙ, for one or more predefined time stamp values.

In these embodiments, the control and supply module 1040 may be configured to determine detection of a performance drift on the basis of the predicted anode voltage values PVa0ₙ and/or the predicted perveance values PGₙ. The control and supply module 1040 may also be configured to apply the predicted anode voltage value(s) PVa0ₙ. This embodiment has the advantage of compensating for the ageing of the tube 1020-n by reducing the number of measurements to be taken (i.e. frequency of correction modes to be activated) and the frequency of calibration modes to be activated.

Moreover, the control and supply module 1040 comprises one or more specific integrated circuits (not shown in the figures) and/or a digital circuit. For example and without limitation, a digital circuit may be any microcontroller. The various units (and the correction and control modes) may be implemented using one or more of these circuits. In particular, the measuring unit 1044 may be implemented on the basis of a single measuring circuit.

The various embodiments of the invention have the advantage of facilitating the adjustment of the operating point of the various travelling wave tubes of the satellite and thus of allowing control of the dispersion of the perveance of each of the tubes of the system due to their ageing and variations in temperature. The activation and implementation of the calibration mode have the advantage of requiring very little or no external manual intervention, and of being able to be carried out quickly, for a few hundred milliseconds or so, with limited impact on radio frequency signal traffic from the satellite 10.

Moreover, the various embodiments of the invention have the advantage of minimizing the wiring and the number of measuring circuits, and thus also reducing its cost.

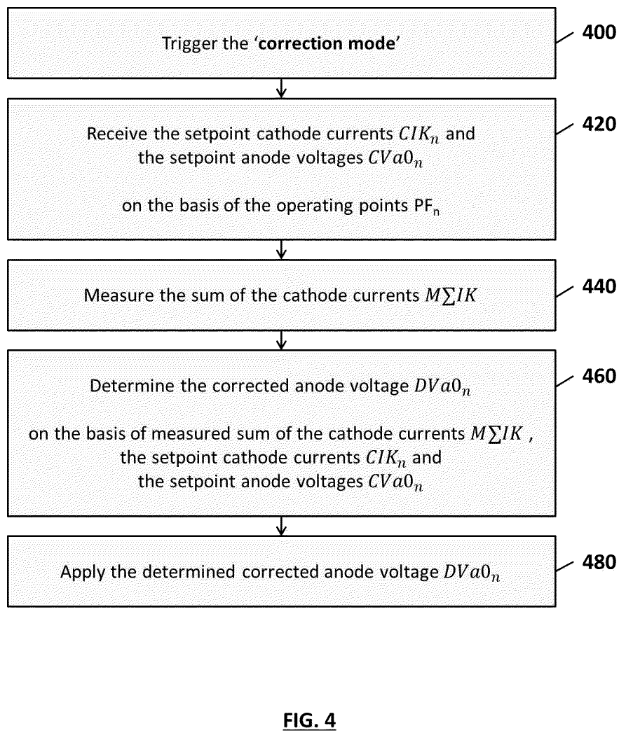

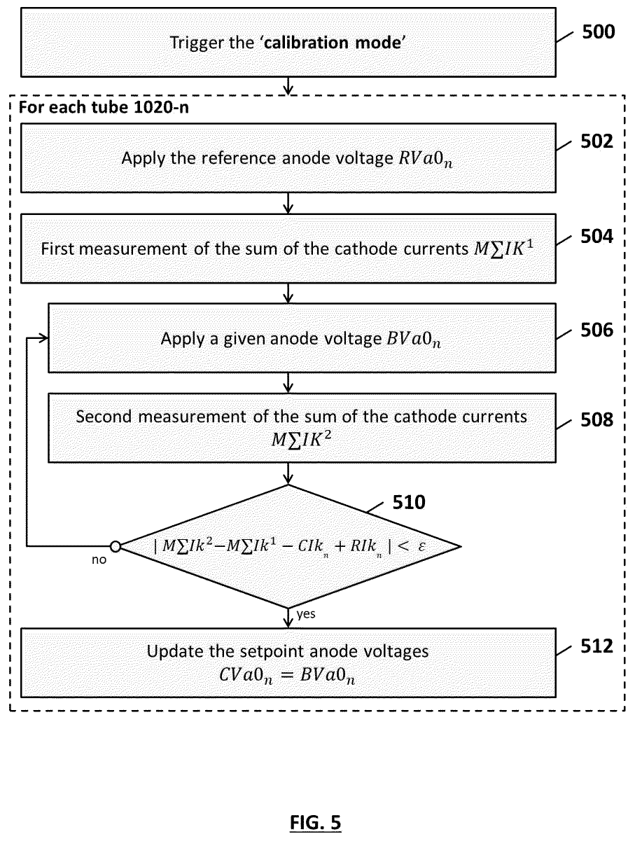

FIG. 4 and FIG. 5 are flowcharts describing the method, implemented by a satellite system 10 and in particular by a modular radio frequency signal amplifier device 100, for controlling operation and the adjustment of the high-voltage power supply vis-à-vis travelling wave tubes, according to embodiments of the invention.

In step 400, the correction mode is activated while each tube 1020-n is used according to an operating point PFₙ.

In step 420, for each tube 1020-n, the cathode current setpoint value CIkₙ and the anode voltage setpoint value Va0ₙ, which are associated with the operating point PFₙ, are received.

In step 440, in response to activation of the correction mode, the value of the sum of the cathode currents MΣIk of the tubes 1020-n is measured by the control and supply module 1040.

A person skilled in the art will readily understand that steps 400, 420 and 440 may be carried out simultaneously and/or in a different order, for example a given order defined by the module 1040.

In step 460, for each tube 1020-n, the corrected anode voltage value DVa0ₙ is determined on the basis of the value of the measured sum MΣIk of the cathode currents, the cathode current setpoint value CIkₙ and the anode voltage setpoint value CVa0ₙ.

In step 480, for each tube 1020-n, the corrected anode voltage value DVa0ₙ is applied to the tube 1020-n.

In step 500, the calibration mode is activated.

In step 502, in response to activation of the calibration mode, the anode voltage reference value RVa0ₙ is applied to a single tube 1020-n to be calibrated.

In step 504, a first value of the sum of the calibration cathode currents MΣIk¹ is measured.

In step 506, a given anode voltage value BVa0ₙ is applied to this single tube 1020-n to be calibrated.

In step 508, a second value of the sum of the calibration cathode currents MΣIk² is measured.

In step 510, a comparison is made between the calibration accuracy setpoint ϵ and a function defined on the basis of the second value of the measured sum MΣIk² of the calibration cathode currents, the first value of the measured sum MΣIk¹ of the calibration cathode currents, the cathode current setpoint value CIkₙ and the cathode current reference value RIkₙ.

In step 512, an update of the calibration table is performed according to the comparison.

A person skilled in the art will understand that the system and the method according to the embodiments of the invention or sub-elements of this system may be implemented in various ways by hardware, software, or a combination of hardware and software, in particular in the form of program code that may be distributed as a program product, in various forms.

The invention is not limited to the embodiments described above by way of non-limiting example. It encompasses all variant embodiments that might be envisaged by a person skilled in the art. In particular, a person skilled in the art will understand that the invention is not limited to the various modules and units of the system and in particular to the various variants of the invention for determining the corrected anode voltage value that have been described by way of non-limiting example.

1. A satellite system comprising a radio frequency signal amplifier device, the amplifier device comprising a control and supply module and a plurality N of travelling wave tubes, the control and supply module being configured to apply, for at least one of said tubes, an anode voltage operating value Va0ₙ, the tube generating a cathode current Ik in response to application of said anode voltage operating value Va0ₙ, wherein the control and supply module is configured to measure at least one sum of the cathode currents MΣIk that is associated with said plurality N of travelling wave tubes, said at least one measurement of the sum of the cathode currents being implemented on the basis of a single measuring circuit, the control and supply module being configured to determine at least one corrected anode voltage operating value associated with said at least one of said tubes on the basis of said at least one measurement of the sum of the cathode currents, the control and supply module being moreover configured to apply said at least one associated corrected anode voltage operating value to said at least one of said tubes.

2. The system according to claim 1, wherein each tube is associated with a given operating point PFₙ associated with a cathode current setpoint value CIkₙ and an anode voltage setpoint value CVa0ₙ, the control and supply module being configured to apply said anode voltage setpoint value (CVa0ₙ) to each tube, and wherein the control and supply module is configured to activate a correction mode and to perform, during said correction mode:
a single measurement of the sum of the cathode currents (MΣIk) that is associated with said plurality N of travelling wave tubes at the operating points (PFₙ),
for each tube, a determination of a corrected anode voltage value DVa0ₙ on the basis of said single measured sum of the cathode currents MΣIk, said cathode current setpoint value CIkₙ and said anode voltage setpoint value CVa0ₙ,
the control and supply module being moreover configured to apply, during said correction mode, said associated corrected anode voltage value DVa0ₙ to each tube.

3. The system according to claim 2, wherein the determination, for each tube, of said corrected anode voltage value DVa0ₙ is performed on the basis of an estimated perveance value DGₙ and said cathode current setpoint value CIkₙ, said corrected anode voltage value DVa0ₙ being defined by:
$$DVa {0}_{n} = {( \frac{{CIK}_{n}}{{DG}_{n}} )}^{+ 2 / 3} .$$

4. The system according to claim 2, wherein the determination, for each tube, of said corrected anode voltage value DVa0ₙ of the travelling wave tube is performed on the basis of a derivative formula for the cathode current with respect to the anode voltage of the tube at the operating point PFₙ.

5. The system according to claim 2, wherein the control and supply module is configured to moreover perform, during said correction mode, a determination of a drift ratio QΣIK on the basis of said single measured sum of the cathode currents MΣIk and a sum of said cathode current setpoint values CIkₙ of said plurality N of tubes.

6. The system according to claim 2, wherein application, during said correction mode, of the corrected anode voltage value DVa0ₙ to the tube is performed in response to a detection of a performance drift of at least one tube from said plurality N of travelling wave tubes.

7. The system according to claim 6, wherein the control and supply module comprises a data set comprising the stored operating points PFₙ, and wherein said performance drift is determined on the basis of a comparison of at least one estimated perveance value DGₙ with a perveance setpoint value CGₙ included in said data set.

8. The system according to claim 5, wherein the control and supply module comprises a data set comprising the PFₙ stored operating points, and wherein said performance drift is determined on the basis of a comparison of the drift ratio QΣIK with a drift threshold included in said data set.

9. The system according to claim 6, wherein said performance drift is determined on the basis of a comparison, for at least one of said tubes, of said corrected anode voltage value DVa0ₙ with said associated anode voltage setpoint value CVa0ₙ.

10. The system according to claim 2, wherein the control and supply module comprises an internal clock and wherein the correction mode is activated in response to a detection of a predefined time stamp.

11. The system according to claim 2, wherein the control and supply module comprises an internal clock and a data set comprising the stored operating points PFₙ, the control and supply module being configured to store in a calibration table and to associate a time stamp with said corrected anode voltage value DVa0ₙ and/or said estimated perveance value DGₙ, and to store, each time the correction mode is activated, said corrected anode voltage value DVa0ₙ and/or said estimated perveance value DGₙ in said data set, and wherein the control and supply module is moreover configured to calculate, for at least one tube from said plurality N of travelling wave tubes, a trend curve on the basis of said data set, and to estimate at least one predicted anode voltage value PVa0ₙ and/or a predicted perveance value PGₙ, associated with a predefined subsequent time stamp value.

12. The system according to claim 1, wherein each tube is associated with a given operating point PFₙ associated with an anode voltage setpoint value CVa0ₙ and a cathode current setpoint value CIkₙ, and wherein the control and supply module is configured to activate a calibration mode and to perform, during said calibration mode:
for a single tube from said plurality N of travelling wave tubes, an application of a first anode voltage value to the tube,
a first measurement of the sum of the calibration cathode currents MΣIk¹ that is associated with said plurality N of travelling wave tubes,
for said single tube, an application of a given second anode voltage value BVa0ₙ to the tube,
a second measurement of the sum of the calibration cathode currents MΣIk² that is associated with said plurality N of travelling wave tubes,
a comparison of said first and second measurements of the sum of the calibration cathode currents MΣIk¹ and MΣIk²;
the control and supply module being moreover configured to perform an update of said anode voltage setpoint value CVa0ₙ on the basis of said given second anode voltage value BVa0ₙ and according to said comparison.

13. The system according to claim 12, wherein said first anode voltage value is an anode voltage reference value RVa0ₙ associated with a cathode current reference value RIkₙ, and wherein, for said single tube, said comparison is moreover performed on the basis of a calibration accuracy setpoint ϵ, said cathode current setpoint value CIkₙ and said cathode current reference value RIkₙ, such that

|MΣIk²−MΣIk¹−CIkₙ+RIkₙ|<ϵ.

14. The system according to claim 12, wherein the calibration mode is activated in response to detection of a performance drift.

15. A method for controlling and supplying power to a plurality of N travelling wave tubes, the method being implemented in a satellite system comprising said travelling wave tubes, the method comprising an initial step of applying an anode voltage operating value Va0ₙ to at least one of said tubes, the tube generating a cathode current Ik in response to application of said anode voltage operating value Va0ₙ, wherein the method comprises the steps of:
measuring at least one sum of the cathode currents that is associated with said plurality N of travelling wave tubes, said at least one measurement of the sum of the cathode currents being implemented on the basis of a single measuring circuit,
determining at least one corrected anode voltage operating value associated with said at least one of said tubes on the basis of said at least one measurement of the sum of the cathode currents,
applying said at least one associated corrected anode voltage operating value to said at least one of said tubes.
